(19) United States
(12) Patent Application Publication
(10) Pub. No.: US 2025/0242467 A1
(43) Pub. Date: Jul. 31, 2025

(54) POLISHING METHOD AND SUBSTRATE TREATING APPARATUS

(71) Applicant: SCREEN Holdings Co., Ltd., Kyoto (JP)

(72) Inventors: Hiroaki ISHII, Kyoto (JP); Junichi ISHII, Kyoto (JP)

(21) Appl. No.: 18/693,370

(22) PCT Filed: Apr. 19, 2022
(86) PCT No.: PCT/JP2022/018165

§ 371 Date: Mar. 17, 2025

(30) Foreign Application Priority Data
Sep. 24, 2021 (JP) 2021-155331

(51) Int. Cl. B24B 49/14; B24B 27/033; B24B 37/04; B24B 37/34; B24B 49/12; B24B 51/00

(52) U.S. Cl. CPC B24B 49/14; B24B 27/033; B24B 37/042; B24B 37/34; B24B 49/12; B24B 51/00

(57) ABSTRACT

This disclosure relates to a polishing method and a substrate treating apparatus. The polishing method includes a rotating step of rotating a substrate W in a horizontal posture, an etching step of supplying an etching solution to a back face of the substrate W to remove a film formed on the back face of the substrate W, and a polishing step of polishing the back face of the substrate W in a chemo-mechanical grinding manner by contacting a polisher 96 against the back face of the substrate W after the film on the back face of the substrate W is removed, the polisher 96 having a resin body where abrasive grains are distributed.

### TECHNICAL FIELD

The present invention relates to a polishing method for polishing a back face of a substrate and a substrate treating apparatus. Examples of substrates include semiconductor substrates, substrates for flat panel displays (FPDs), glass substrates for photomasks, substrates for optical disks, substrates for magnetic disks, ceramic substrates, and substrates for solar cells. Examples of the FPDs include liquid crystal display devices and organic electroluminescence (EL) display devices. Here, the back face of the substrate is a face where no electronic circuits are formed, which is opposite to a front face of the substrate as a face (device face) where electronic circuits are formed.

### BACKGROUND ART

A polishing device for polishing the back face of the substrate includes a polishing head and a holding rotator. The polishing device supplies a polishing solution, and further causes the polishing head to contact against the back face of the substrate for polishing the substrate (see, for example, Patent Literature 1). Moreover, the holding rotator rotates the substrate while holding the substrate in a horizontal posture.

Another type of polishing devices is a grinding device that performs dry chemo-mechanical grinding (CMG: Chemo-Mechanical Grinding) to a substrate (see, for example, Patent Literature 2). The grinding device includes a synthetic grindstone and a holding rotator. The synthetic grindstone is formed by fixing polishing agents (abrasive grains) with a resin binder. The grinding device grinds a substrate by contacting the synthetic grindstone against the substrate. Also, there is a substrate treating apparatus provided with a polisher for removing contaminants or contact marks on a back face of a substrate (see, for example, Patent Literature 3).

### PRIOR ART DOCUMENT

### Patent Literature

[Patent Literature 1] Japanese Patent Publication No. 6162417
[Patent Literature 2] Japanese Patent Publication No. 6779540
[Patent Literature 3] Japanese Patent Publication No. 6740065

### SUMMARY OF INVENTION

### Technical Problem

The currently-used device having such a configuration has the following drawback. The drawback is defocus (so-called out of focus) by an extreme ultraviolet (EUV) exposing machine due to a substrate flatness of a back face of the substrate (e.g., wafer) in recent years. One cause of poor flatness is considered a scratch. As a result, in order to scrape off the scratch, it has been studied to adopt the synthetic grindstone as a polisher in Patent Literature 2. However, it is found that there is a case where polishing is not performed satisfactorily even when a polisher polishes the back face of the substrate.

The present invention has been made regarding the state of the art noted above, and its one object is to provide a polishing method and a substrate treating apparatus that can perform polishing treatment satisfactorily.

### Solution to Problem

The present invention is constituted as stated below to achieve the above object. One aspect of the present invention provides a polishing method including a rotating step of rotating a substrate in a horizontal posture, an etching step of supplying an etching solution to a back face of the substrate to remove a film formed on the back face of the substrate, and a polishing step of polishing the back face of the substrate in a chemo-mechanical grinding manner by contacting a polisher against the back face of the substrate after the film on the back face of the substrate is removed, the polisher having a resin body where abrasive grains are distributed.

With the polishing method according to the present invention, the polisher contacts against the back face of the substrate to polish the back face of the rotating substrate in the chemo-mechanical grinding manner. Here, it is found that, when the thin film is formed on the back face of the substrate, the polishing cannot be performed suitably due to the film. Then, the film formed on the back face of the substrate is removed by the etching step prior to the polishing step. This can perform the polishing treatment suitably.

Moreover, it is preferred that the polishing method described above further includes a heating step of heating the substrate during polishing. When the substrate is heated, a polishing rate can increase. This can shorten time for polishing treatment.

Moreover, it is preferred that the polishing method described above further includes a controlling step of adjusting a polishing rate by controlling a heating temperature of the substrate in the heating step. Raising and lowering the heating temperature of the substrates allows increase and decrease of the polishing rate.

Moreover, it is preferred in the polishing method described above that, in the controlling step, the polishing rate is adjusted by controlling at least one selected from a contact pressure of the polisher against the substrate, a moving speed of the polisher, a rotation speed of the polisher, and a rotation speed of the substrate. For example, raising the heating temperature of the substrate while keeping the polishing rate allows decreased contact pressure of the polisher against the substrate. This can suppress load of the substrate caused by the contact pressure. That is, excess pushing against the substrate W can be prevented.

Moreover, in the polishing method described above, the etching step exemplarily includes removal of a silicon oxide film. Moreover, in the polishing method described above, the etching step exemplarily includes removal of a silicon nitride film. Moreover, in the polishing method described above, the etching step exemplarily includes removal of a polysilicon film.

Moreover, it is preferred that the polishing method described above further includes an inspecting step of detecting a scratch formed on the back face of the substrate prior to the etching step by an inspecting unit, and that the etching step is performed when the inspecting unit detects the scratch. This can scrape the detected scratch, i.e., a selected scratch, in the polishing step after the etching step.

Moreover, it is preferred in the polishing method described above that, in the inspecting step, the inspecting unit detects the scratch formed on the back face of the substrate and determines a depth of the scratch when the scratch is detected, that the etching step is performed when the inspecting unit detects the scratch, and that, in the polishing step, the back face of the substrate is polished until a thickness corresponding to the depth of the scratch determined by the inspecting unit is scraped off. Accordingly, the depth of the scratch is recognized, achieving a suitable amount of polishing in a thickness direction of the substrate.

Moreover, it is preferred that the polishing method described above further includes a detecting step of detecting a scratch formed on the back face of the substrate between the etching step and the polishing step by an inspecting unit, and that the polishing step is performed when the inspecting unit detects the scratch. This can scrape the scratch detected after the etching step, i.e., a selected scratch, in the polishing step.

Another aspect of the present invention provides a substrate treating apparatus including a holding rotator configured to rotate a substrate while holding the substrate in a horizontal posture, a polisher having a resin body where abrasive grains are distributed, an etching solution supply nozzle configured to supply an etching solution to a back face of the substrate held by the holding rotator, and a controller, and that the controller causes the etching solution supply nozzle to supply the etching solution to the back face of the substrate to remove a film formed on the back face of the substrate, and causes the polisher to contact against the back face of the rotating substrate after the film on the back face of the substrate is removed to polish the back face of the substrate in a chemo-mechanical grinding manner.

With the substrate treating apparatus according to the present invention, the polisher contacts against the back face of the substrate to polish the back face of the rotating substrate in the chemo-mechanical grinding manner. Here, it is found that, when the thin film is formed on the back face of the substrate, the polishing cannot be performed suitably due to the film. Then, the film formed on the back face of the substrate is removed by etching treatment prior to polishing treatment. This can perform the polishing treatment suitably.

Moreover, it is preferred that the substrate treating apparatus described above further includes a heating member configured to heat the substrate, and that after the film on the back face of the substrate is removed, the controller causes the polisher to contact against the back face of the substrate heated while being rotated to polish the back face of the substrate in the chemo-mechanical grinding manner.

### Advantageous Effects of Invention

The polishing method and the substrate treating apparatus according to the present invention can perform polishing treatment satisfactorily.

### BRIEF DESCRIPTION OF DRAWINGS

FIG. 1 is a plan view illustrating a configuration of a substrate treating apparatus according to a first embodiment.

FIGS. 2(a) to 2(d) each illustrate an inversion unit.

FIG. 3 is a side view illustrating a construction of a polishing unit.

FIG. 4(a) is a plan view illustrating a construction of a holding rotator, and FIG. 4(b) is a longitudinal sectional view of the construction of the holding rotator partially enlarged.

FIG. 5 illustrates a construction of a polishing mechanism of the polishing unit.

FIG. 6 illustrates a construction of an inspecting unit.

FIG. 7 is a flow chart illustrating operation of the substrate treating apparatus according to the first embodiment.

FIG. 8(a) is a longitudinal sectional view schematically illustrating a substrate prior to an etching step, FIG. 8(b) is a longitudinal sectional view schematically illustrating the substrate after the etching step (prior to back polishing step), and FIG. 8(c) is a longitudinal sectional view schematically illustrating the substrate after the back polishing step.

FIG. 9 is a flow chart illustrating details of a wet-etching step.

FIG. 10 illustrates a relationship between a heating temperature and a polishing rate of the substrate.

FIG. 11 is a flow chart showing procedures of a substrate cleaning step.

FIG. 12 is a flow chart illustrating operation of a substrate treating apparatus according to a second embodiment.

FIG. 13 illustrates a relationship between a heating temperature of a substrate and a contact pressure (press) of a polisher.

FIG. 14 is a side view illustrating a construction of a polishing unit according to a fourth embodiment.

FIG. 15 is a side view illustrating a construction of a liquid treating unit according to the fourth embodiment.

FIGS. 16(a) and (b) each illustrate a heater for heating the polisher.

FIG. 17 illustrates a relationship between a combination of heating members and a heating temperature of a substrate.

### FIRST EMBODIMENT

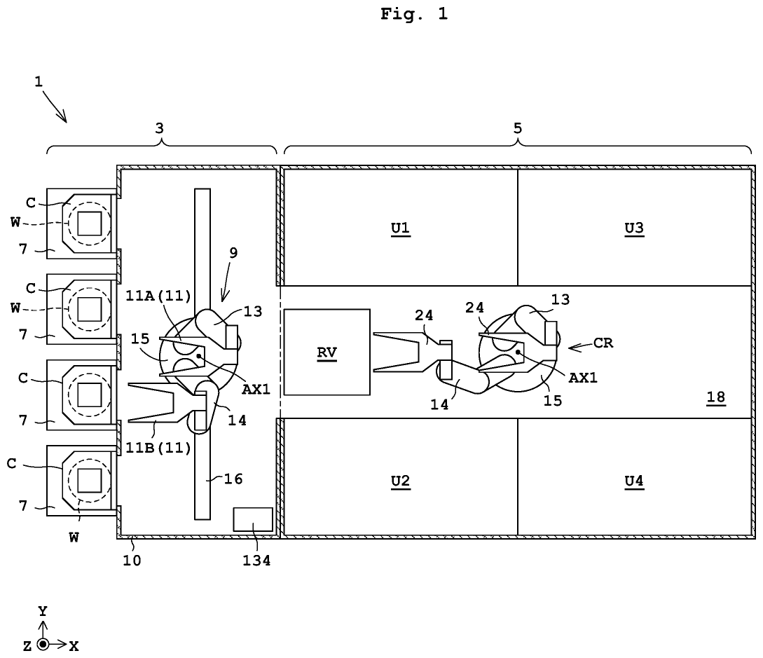

A first embodiment of the present invention will now be described with reference to the drawings. FIG. 1 is a plan view illustrating a configuration of a substrate treating apparatus according to the first embodiment.

### (1) Construction of Substrate Treating Apparatus

Reference is made to FIG. 1. The substrate treating apparatus 1 includes an indexer block 3 and a treating block 5. Here, the block is also called an area.

The indexer block 3 includes a plurality of (e.g., four) carrier platforms 7 and an indexer robot 9. The four carrier platforms 7 are arranged on an outer face of a housing 10. The four carrier platforms 7 are each used for placing a carrier C thereon. The carrier C accommodates a plurality of substrates W. Each of the substrates W in the carrier C is in a horizontal posture while a device face thereof is directed upward (faces upward). For example, a FOUP (Front Open Unified Pod) or SMIF (Standard Mechanical Inter Face) pod, or an open cassette is used as the carrier C. The substrate W is a silicon substrate, and formed in a disk shape, for example.

The indexer robot 9 takes a substrate W from the carrier C placed on the carrier platform 7, and also accommodates a substrate W into the carrier C. The indexer robot 9 is arranged inside of the housing 10. The indexer robot 9 includes two hands 11 (11A, 11B), two articulated arms 13, 14, a lifting and lowering board 15, and a guide rail 16. The two hands 11 each hold a substrate W. A first hand 11A is connected to a front end of the articulated arm 13. A second hand 11B is connected to a front end of the articulated arm 14.

The two articulated arms 13 and 14 are each of a SCARA type, for example. Each of the two articulated arms 13 and 14 has a proximal end attached to the lifting and lowering board 15. The lifting and lowering board 15 is configured so as to be extendible and contractible in an up-down direction. Accordingly, the two hands 11 and the two articulated arms 13 and 14 are moved upward and downward. The lifting and lowering board 15 is rotatable around a central axis AX1 extending in an up-down direction. This achieves changing of orientation of the two hands 11 and the two articulated arms 13 and 14. The lifting and lowering board 15 of the indexer robot 9 is movable along the guide rail 16 extending in a Y-direction.

The indexer robot 9 includes a plurality of electric motors. The indexer robot 9 is driven by the plurality of electric motors. The indexer robot 9 transports a substrate W between the carrier C placed on each of the four the carrier platforms 7 and an inversion unit RV mentioned later.

The treating block 5 includes a transportation space 18, a substrate transporting robot CR, the inversion unit RV, and a plurality of (e.g., eight) treating units (treatment chamber) U1 to U4. In FIG. 1, the treating units U1 to U4 are formed in two layers in the up-down direction, for example. The treating unit U1 is an inspecting unit 20. The treating units U2, U3, and U4 are a polishing unit 22. The number and types of the treating units are appropriately variable.

The transportation space 18 has the substrate transporting robot CR and the inversion unit RV arranged therein. The inversion unit RV is arranged between the indexer robot 9 and the substrate transporting robot CR. The treating units U1 and U3 are arranged in a row along the transportation space 18 in an X-direction. Moreover, the treating units U2 and U4 are arranged in a row along the transportation space 18 in the X-direction. The transportation space 18 is arranged between the treating units U1, U3 and the treating units U2, U4.

The substrate transporting robot CR is constructed in substantially the same manner as that of the indexer robot 9. That is, the substrate transporting robot CR includes two hands 24. Here, the other constructions of the substrate transporting robot CR have the same numerals as those of the indexer robot 9. The lifting and lowering board 15 of the substrate transporting robot CR is fixed to the floor, which differs from the lifting and lowering board 15 of the indexer robot 9. On the other hand, the lifting and lowering board 15 of the substrate transporting robot CR includes a guide rail extending in the X-direction, and is movable in the X-direction. Such construction may be adopted. The substrate transporting robot CR transports the substrate W between the inversion unit RV and the eight treating units U1 to U4.

### (1-1) Inversion Unit RV

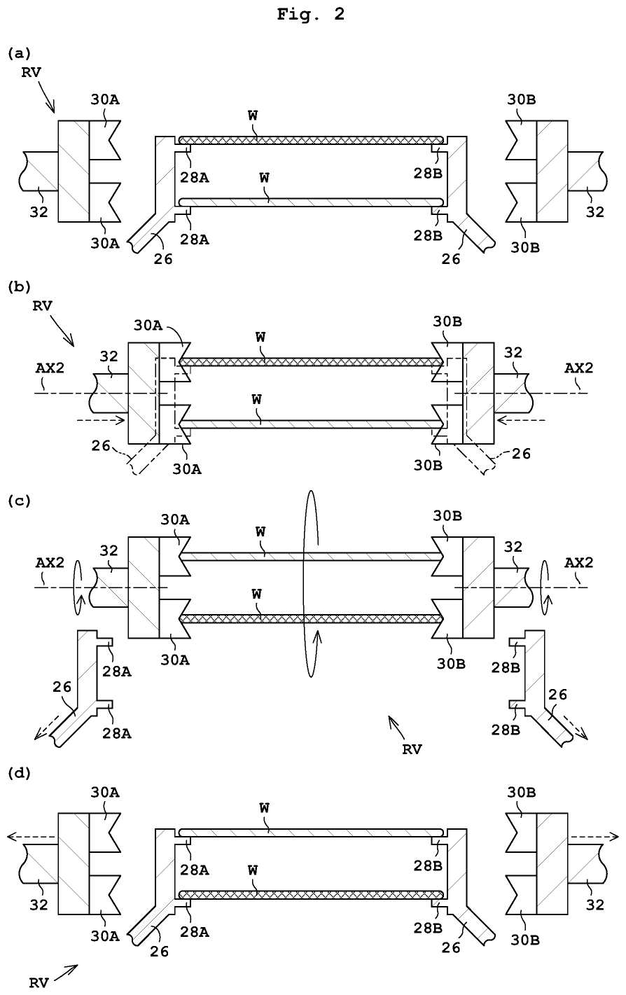

FIGS. 2(a) to 2(d) are each an explanatory view of the inversion unit RV. The inversion unit RV includes supporting members 26, mount members 28A, 28B, grasping members 30A, 30B, slide shafts 32, and a plurality of electric motors (not shown). Right and left supporting members 26 have the mount members 28A and 28B, respectively. Moreover, right and left slide shafts 32 have the grasping members 30A and 30B, respectively. The electric motors drive the supporting members 26 and the slide shafts 32. Here, the mount members 28A and 28B and the grasping members 30A and 30B are positioned so as not to interfere each other.

Reference is made to FIG. 2(a). The substrate W, transported by the indexer robot 9, for example, is placed on the mount members 28A and 28B. Reference is made to FIG. 2(b). The right and left slide shafts 32 approach each other along a horizontal axis AX2. Accordingly, the two-paired grasping members 30A and 30B sandwich two substrates W individually. Reference is made to FIG. 2(c). Then, the right and left mount members 28A and 28B move downward and away from each other. Then, the grasping members 30A and 30B rotate by 180 degrees around the horizontal axis AX2. This reverses each of the substrates W.

Reference is made to FIG. 2(d). Then, the right and left mount members 28A and 28B move upward while approaching each other. Then, the right and left slide shafts 32 move away from each other along the horizontal axis AX2. Accordingly, the grasping members 30A, 30B release the two substrates W, and the two substrates W are placed on the mount members 28A, 28B. In FIGS. 2(a) to 2(d), the inversion unit RV can reverse the two substrates W. Alternatively, the inversion unit RV may be configured to be capable of reversing three or more substrates W.

### (1-2) Polishing Unit 22

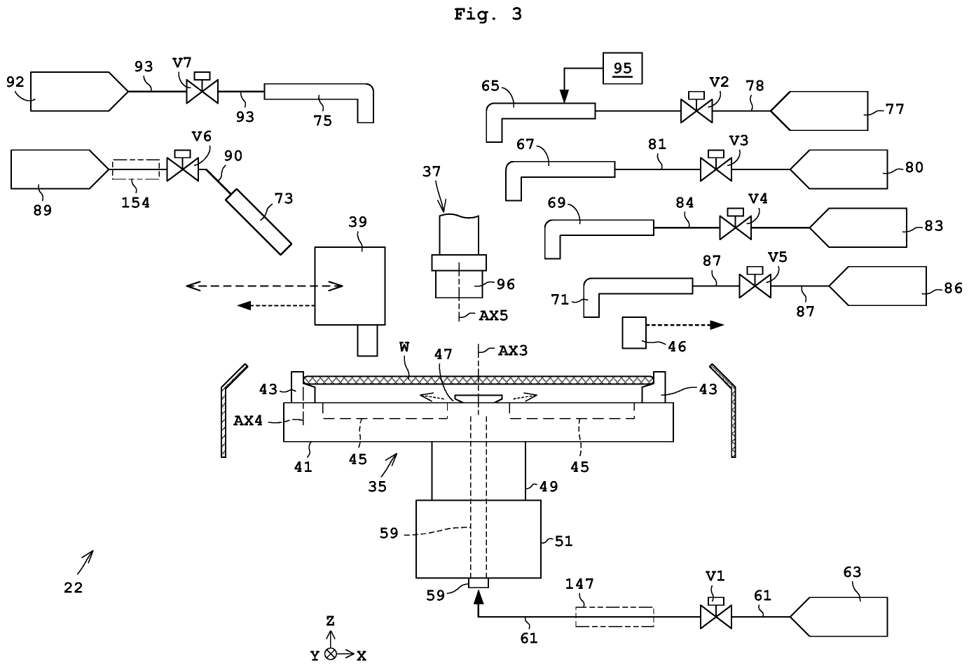

FIG. 3 shows the polishing unit 22. The polishing unit 22 includes a holding rotator 35, a polishing mechanism 37, and a substrate thickness measuring device 39. The holding rotator 35 corresponds to the holding rotator in the present invention.

The holding rotator 35 holds one substrate W whose back face is directed upward in a horizontal posture, and rotates the held substrate W. Here, the back face of the substrate W is a face where no electronic circuits are formed, which is opposite to a front face of the substrate W as a face (device face) where electronic circuits are formed. The device face of the substrate W held by the holding rotator 35 is directed downward.

The holding rotator 35 includes a spin base 41, six holding pins 43, a hot plate 45, and a gas ejection port 47. The spin base 41 is formed in a disk shape, and is arranged in a horizontal posture. A rotary axis AX3, extending in the up-down direction, passes the center of the spin base 41. The spin base 41 is rotatable around the rotary axis AX3.

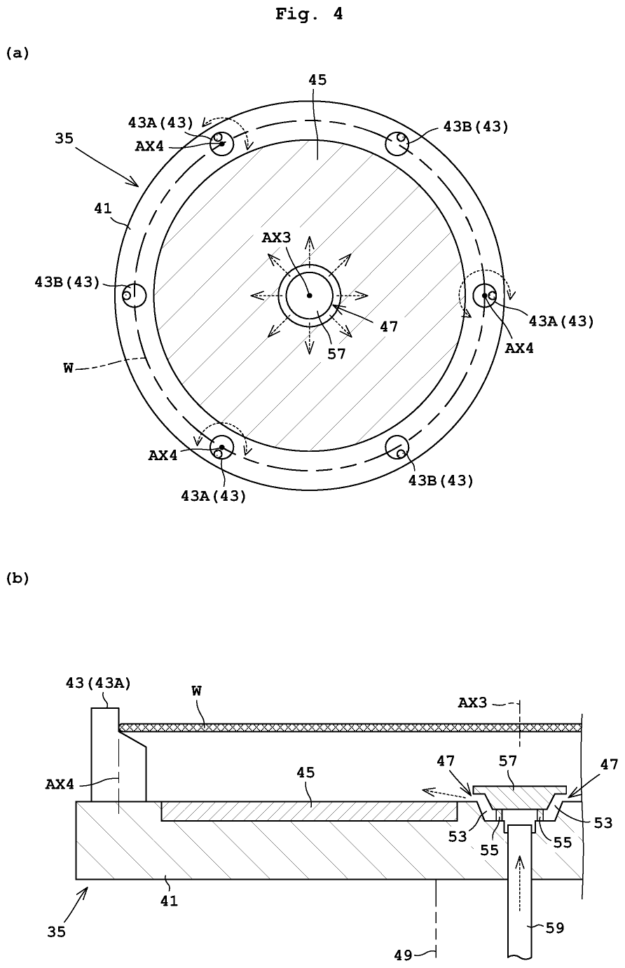

FIG. 4(a) is a plan view of the spin base 41 and the six holding pins 43 of the holding rotator 35. The six holding pins 43 are provided on a top face of the spin base 41. The six holding pins 43 are provided in a ring shape so as to surround the rotary axis AX3. Moreover, the six holding pins 43 are provided at equal intervals near an outer edge of the spin base 41. The six holding pins 43 cause the substrate W to be placed apart from the spin base 41 and the hot plate 45 mentioned later. Moreover, the six holding pins 43 are configured so as to sandwich a side face of the substrate W. That is, the six holding pins 43 can hold the substrate W while the substrate W is apart from the top face of the spin base 41.

The six holding pins 43 are divided into three holding pins 43A that rotate, and three holding pins 43B that do not rotate. The three holding pins 43A are rotatable around a rotary axis AX4 extending in the up-down direction. The three holding pins 43A each rotate around the rotary axis AX4, thereby holding the substrate W and releasing the held substrate W. The holding pins 43A each rotate around the rotary axis AX4 by magnetic suction force or repulsion by a magnet, for example. The number of holding pins 43 is not limited to six, and the number only needs to be three or more. The substrate W may be held by three or more holding pins 43 including a holding pin 43A that rotates and a holding pin 43B that does not rotate.

The hot plate 45 is provided on the top face of the spin base 41. The hot plate 45 includes therein an electric heater having a nichrome wire, for example. The hot plate 45 is formed in a toroidal and disk shape. The hot plate 45 heats the substrate W with radiant heat. Moreover, the hot plate 45 heats gas ejected from the gas ejection port 47, mentioned later, thereby heating the substrate W through the gas. A temperature sensor 46 of a non-contact type determines a temperature of the substrate W. The temperature sensor 46 includes a detecting element configured to detect infrared rays emitted from the substrate W. Here, the hot plate 45 corresponds to the heating member in the present invention. Moreover, in the embodiment 1, the polishing unit 22 does not include heaters 147, 154 (see FIG. 3) mentioned later.

A shaft 49 is provided on a lower face of the spin base 41. A rotating mechanism 51 includes an electric motor. The rotating mechanism 51 rotates the shaft 49 around the rotary axis AX3. That is, the rotating mechanism 51 rotates the substrate W, held by the six holding pins 43 (specifically, three holding pins 43A) provided on the spin base 41, around the rotary axis AX3.

Reference is made to FIG. 3 and FIG. 4(b). The gas ejection port 47 is opened in the top face of the spin base 41 and is provided at a center portion of the spin base 41. A flow path 53 whose upper part is opened is provided at the center of the spin base 41. Moreover, an ejection member 57 is provided in the flow path 53 via a plurality of spacers 55. The gas ejection port 47 is configured by a ring opening that is formed by a gap between The ejection member 57 and the flow path 53.

A gas supplying pipe 59 is provided along the rotary axis AX3 so as to pass through the shaft 49 and the rotating mechanism 51. A gas pipe 61 feeds gas (inert gas such as nitrogen gas) from a gas supplying source 63 to the gas supplying pipe 59. An on-off valve V1 is provided on the gas pipe 61. The on-off valve V1 performs and stops supply of the gas. When the on-off valve V1 is opened, the gas ejection port 47 ejects gas. When the on-off valve V1 is closed, the gas ejection port 47 does not eject gas. The gas ejection port 47 ejects gas in such a manner that the gas flows in a gap between the substrate W and the spin base 41 from a portion adjacent to the center of the substrate W toward the outer edge of the substrate W.

The following describes a construction for supplying a chemical liquid, a rinse liquid, and gas. The polishing unit 22 includes a first chemical liquid nozzle 65, a second chemical liquid nozzle 67, a first cleaning liquid nozzle 69, a second cleaning liquid nozzle 71, a rinse liquid nozzle 73, and a gas nozzle 75.

Here, the first chemical liquid nozzle 65 and the second chemical liquid nozzle 67 correspond to the etching solution supply nozzle in the present invention. Moreover, a first chemical liquid and a second chemical liquid to be mentioned later correspond to th etching solution in the present invention.

The first chemical liquid nozzle 65 is connected to a chemical liquid pipe 78 that feed a first chemical liquid from a first chemical liquid supplying source 77. The first chemical liquid is, for example, hydrofluoric acid (HF). An on-off valve V2 is provided on the chemical liquid pipe 78. The on-off valve V2 performs and stops supply of the first chemical liquid. When the on-off valve V2 is opened, the first chemical liquid is supplied from the first chemical liquid nozzle 65. Moreover, when the on-off valve V2 is closed, supply of the first chemical liquid from the first chemical liquid nozzle 65 stops.

The second chemical liquid nozzle 67 is connected to a chemical liquid pipe 81 that feed a second chemical liquid from a second chemical liquid supplying source 80. The second chemical liquid is, for example, a mixed liquid of hydrofluoric acid (HF) and nitric acid (HNO₃), Tetramethylammonium hydroxide (TMAH), or hot diluted ammonia water (Hot-dNH₄OH). An on-off valve V3 is provided on the chemical liquid pipe 81. The on-off valve V3 performs and stops supply of the second chemical liquid.

The first cleaning liquid nozzle 69 is connected to a cleaning liquid pipe 84 that feed a first cleaning liquid from a first cleaning liquid supplying source 83. The first cleaning liquid is, for example, SC2 or SPM. Here, SC2 is a mixed liquid of hydrochloric acid (HCl), hydrogen peroxide (H₂O₂), and water. SPM is a mixed liquid of sulfuric acid (H₂SO₄) and hydrogen peroxide water (H₂O₂). An on-off valve V4 is provided on the cleaning liquid pipe 84. The on-off valve V4 performs and stops supply of the first cleaning liquid.

The second cleaning liquid nozzle 71 is connected to a cleaning liquid pipe 87 that feed a second cleaning liquid from a second cleaning liquid supplying source 86. The second cleaning liquid is, for example, SC1. SC1 is a mixed liquid of ammonia, hydrogen peroxide water (H₂O₂), and water. An on-off valve V5 is provided on the cleaning liquid pipe 87. The on-off valve V5 performs and stops supply of the second cleaning liquid.

The rinse liquid nozzle 73 is connected to a rinse liquid pipe 90 that feeds a rinse liquid from a rinse liquid supplying source 89. The rinse liquid is, for example, pure water like Deionized Water (DIW) or carbonated water. An on-off valve V6 is provided on the rinse liquid pipe 90. The on-off valve V6 performs and stops supply of the rinse liquid.

The gas nozzle 75 is connected to a gas pipe 93 that feeds gas from a gas supplying source 92. The gas is, for example, inert gas like nitrogen gas. An on-off valve V7 is provided on the gas pipe 93. The on-off valve V7 performs and stops supply of the gas.

The first chemical liquid nozzle 65 is moved by a nozzle moving mechanism 95 in a horizontal direction. The nozzle moving mechanism 95 includes an electric motor. The nozzle moving mechanism 95 may rotate the first chemical liquid nozzle 65 around a vertical axis (not shown) set in advance. Moreover, the nozzle moving mechanism 95 may move the first chemical liquid nozzle 65 in the X-direction and the Y-direction. Moreover, the nozzle moving mechanism 95 may move the first chemical liquid nozzle 65 in the up-down direction (Z-direction). Similar to the first chemical liquid nozzle 65, the five nozzles 67, 69, 71, 73, and 75 each may be moved by the nozzle moving mechanism (not shown).

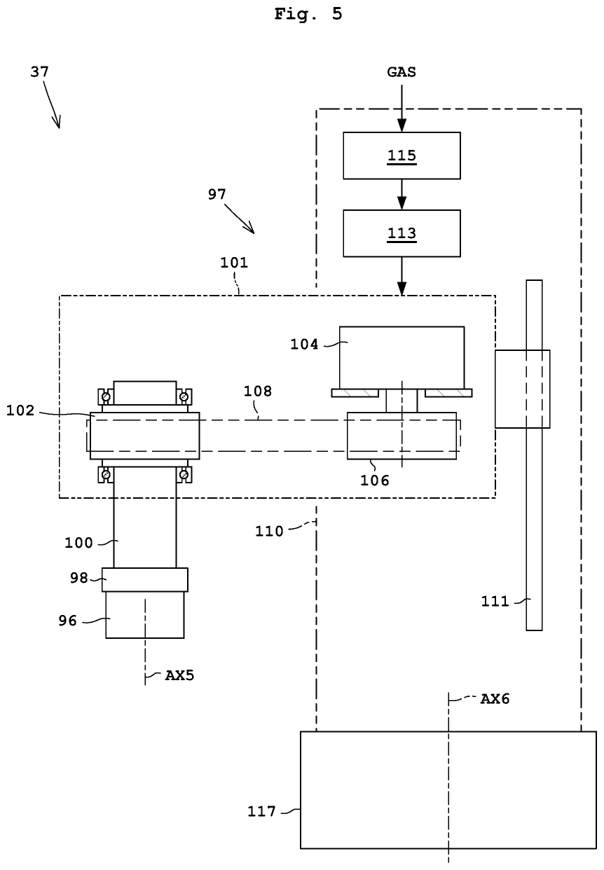

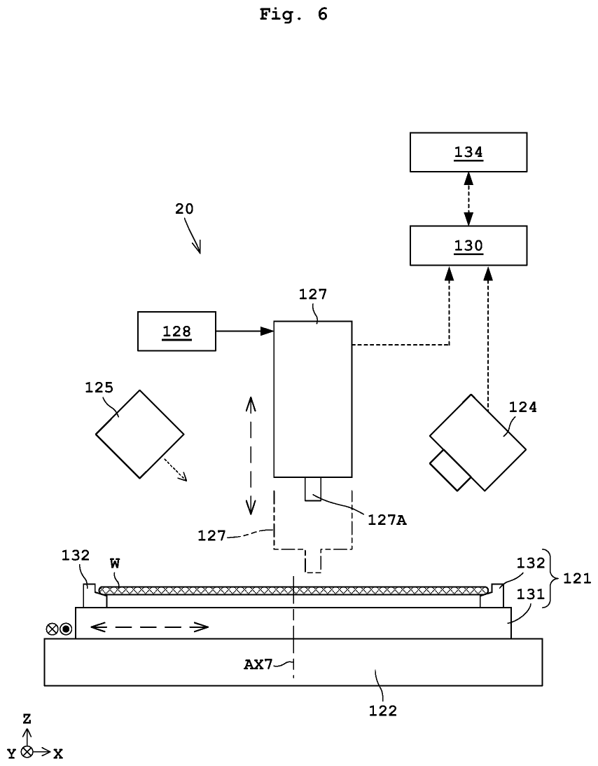

The following describes the configuration of the polishing mechanism 37. The polishing mechanism 37 polishes the back face of the substrate W. FIG. 5 is a side view of the polishing mechanism 37. The polishing mechanism 37 includes a polisher 96 and a polisher moving mechanism 97. The polisher moving mechanism 97 includes an attachment member 98, a shaft 100, and an arm 101.

The polisher (grinder) 96 polishes the back face of the substrate W in a dry chemo-mechanical grinding (CMG) manner. The polisher 96 is formed in a cylindrical shape. The polisher 96 has a resin body in which abrasive grains are distributed. In other words, the polisher 96 is formed by fixing the abrasive grains (polishing agent) with a resin binder. An oxide such as cerium oxide or silica is used as the abrasive grains. It is preferred that the abrasive grain has an average particle size of 10 μm or less. Thermosetting resin such as epoxy resin and phenol resin is used for the resin body and resin binder. Moreover, thermoplastics such as ethyl cellulose may be used for the resin body and resin binder. In this case, polishing is performed such that the thermoplastics is not softened.

Now description will be made of the chemo-mechanical grinding (CMG). In the CMG, grinding is considered to be performed by the following principle. That is, local high temperatures and high pressure in the vicinity of the abrasive grain occur due to contact of the abrasive grain like cerium oxide and an object, leading to generation of a solid phase reaction between the abrasive grain and the object to form silicates. As a result, a surface layer of the object is softened, and the softened surface layer is mechanically removed by the abrasive grains. Here, examples of the polishing include a Chemical Mechanical Polishing (CMP) manner. In this manner, a slurry solution is supplied to a pad which is brought into contact with the object, and the abrasive grains contained in the slurry solution are kept on an uneven surface of the pad to perform chemical mechanical polishing. The present invention adopts the CMG manner.

The polisher 96 is attachable to and detachable from the attachment member 98 via a screw, for example. The attachment member 98 is fixed to a lower end of the shaft 100. A pulley 102 is fixed to the shaft 100. An upper end of the shaft 100 is accommodated in the arm 101. That is, the polisher 96 and the attachment member 98 are attached to the arm 101 via the shaft 100.

An electric motor 104 and a pulley 106 are arranged within the arm 101. The pulley 106 is connected to a rotation output shaft of the electric motor 104. A belt 108 is suspended over the two pulleys 102 and 106. The pulley 106 rotates by the electric motor 104. Rotation of the pulley 106 is transmitted to the pulley 102 and the shaft 100 by the belt 108. Accordingly, the polisher 96 rotates around a vertical axis AX5.

Moreover, the polisher moving mechanism 97 includes a lifting mechanism 110. The lifting mechanism 110 includes a guide rail 111, an air cylinder 113, and an electropneumatic regulator 115. A proximal end of the arm 101 is connected to the guide rail 111 so as to be movable upward and downward. The guide rail 111 guides the arm 101 in the up-down direction. The air cylinder 113 moves the arm 101 upward and downward. The electropneumatic regulator 115 supplies gas, such as air with pressure set in accordance with an electrical signal from a main controller 134 mentioned later, to the air cylinder 113. Now, the lifting mechanism 110 may include a linear actuator, instead of the air cylinder 113, that is driven by an electric motor.

Moreover, the polisher moving mechanism 97 further includes an arm rotating mechanism 117. The arm rotating mechanism 117 includes an electric motor. The arm rotating mechanism 117 rotates the arm 101 and the lifting mechanism 110 around a vertical axis AX6. That is, the arm rotating mechanism 117 rotates the polisher 96 around the vertical axis AX6.

The polishing unit 22 includes the substrate thickness measuring device 39. The substrate thickness measuring device 39 measures a thickness of the substrate W held by the holding rotator 35. The substrate thickness measuring device 39 is configured to emit light in a wavelength range (e.g., 1100 nm to 1900 nm) that is transparent to the substrate W from a light source to a mirror and the substrate W through an optical fiber. Moreover, the substrate thickness measuring device 39 is configured to detect returned light caused by interference of reflected light by the mirror, reflected light reflected on the upper surface of the substrate W, and the reflected light reflected on the lower surface of the substrate W with use of light receiving elements. Then, the substrate thickness measuring device 39 generates a spectral interference waveform representing a relationship between the wavelength of the return light and light intensity, and analyzes the spectral interference waveform to measure a thickness of the substrate W. The substrate thickness measuring device 39 is a known device. The substrate thickness measuring device 39 may be configured so as to be movable by a moving mechanism not shown between a standby position out of the substrate W and a measuring position above the substrate W.

### (1-3) Inspecting Unit 20

FIG. 6 is a side view of the inspecting unit 20. The inspecting unit 20 includes a stage 121, an XY-direction moving mechanism 122, a camera 124, a lighting portion 125, a laser scanning confocal microscope 127, a lifting mechanism 128, and an inspection controller 130.

The stage 121 supports the substrate W, whose back face is directed upward, in a horizontal posture. The stage 121 includes a disk base member 131 and six support pins 132, for example. The six support pins 132 are provided in a ring shape around a central axis AX7 of the base member 131. Moreover, the six support pins 132 are arranged at equal intervals in a circumferential direction. With such a construction, the six support pins 132 can support the outer edge of the substrate W while the substrate W is separated from the base member 131. Moreover, the XY-direction moving mechanism 122 moves the stage 121 in the XY-direction (horizontal direction). The XY-direction moving mechanism 122 includes, for example, two linear actuators each driven by an electric motor.

The camera 124 takes a picture of the back face of the substrate W. The camera 124 includes an image sensor such as a charge-coupled device (CCD) or a complementary metal-oxide semiconductor (CMOS). The lighting portion 125 emits light to a back face of a substrate W. This allows easy observation of a scratch generated on the back face of the substrate W, for example.

The laser scanning confocal microscope 127 is hereunder called a “laser microscope 127”. The laser microscope 127 includes a confocal optical system having a laser light source, an objective lens 127A, an imaging lens, an optical sensor, and a confocal pinhole. The laser microscope 127 captures a plane image by scanning the laser light source in the XY-direction (horizontal direction). Moreover, the laser microscope 127 captures plane images by moving the objective lens 127A in the Z-direction (height direction) relative to the object to be observed. As a result, the laser microscope 127 captures a three-dimensional image (a plurality of plane images) containing a three-dimensional shape. Here, the laser microscope 127 is called a three-dimensional shape measuring device.

The laser microscope 127 captures a three-dimensional image of any scratch generated on the back face of the substrate W. For example, a controller mentioned later determines a depth of the scratch from the three-dimensional shape of the scratch in the captured three-dimensional image. The lifting mechanism 128 moves the laser microscope 127 upward and downward in the up-down direction (Z-direction). The lifting mechanism 128 is formed by a linear actuator driven by an electric motor.

The inspection controller 130 includes one or more processors like a central processing unit (CPU), and a memory unit (not shown), for example. The inspection controller 130 controls each component of the inspecting unit 20. The memory unit of the inspection controller 130 includes at least one selected from a read-only memory (ROM), a random-access memory (RAM), and a hard disk. The memory unit of the inspection controller 130 stores computer program for operating the inspecting unit 20, observed images, an extraction result of the scratch, and a three-dimensional image.

Moreover, the substrate treating apparatus 1 further includes the main controller 134 communicably connected to the inspection controller 130, and a memory unit (not shown). The main controller 134 includes one or more processors like a central processing unit (CPU), for example. The main controller 134 controls each component of the substrate treating apparatus 1. Moreover, the memory unit of the main controller 134 includes at least one selected from a read-only memory (ROM), a random-access memory (RAM), and a hard disk. The memory unit of the main controller 134 stores computer programs and the like for operating the substrate treating apparatus 1. The main controller 134 corresponds to the controller in the present invention.

### (2) Operation of Substrate Treating Apparatus 1

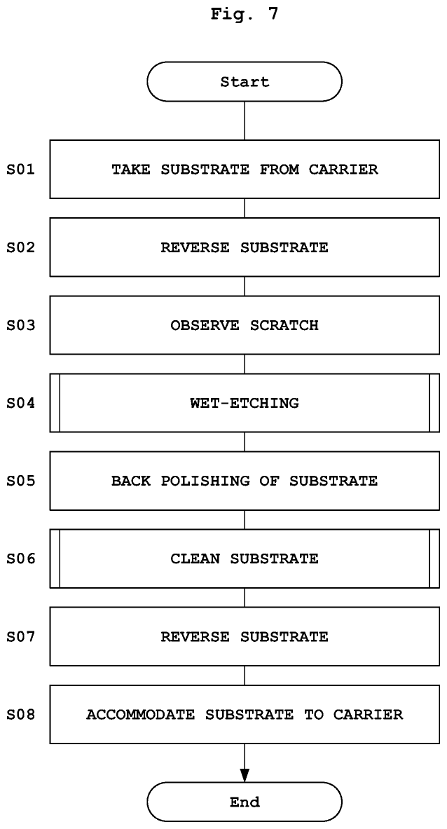

Next, description will be given of operation of the substrate treating apparatus 1 with reference to FIG. 7.

[Step S01] Taking Substrate W from Carrier C

Carriers C are placed on the given carrier platforms 7, respectively. The indexer robot 9 takes a substrate W from the carrier C, and transports the taken substrate W to the inversion unit RV. At this time, the device face of the substrate W is directed upward while the back face of the substrate W is directed downward.

### [Step S02] Reversing Substrate W

When one substrate W or two substrates W are placed on the mount members 28A, 28B by the indexer robot 9, the inversion unit RV reverses the two substrates W as shown in FIGS. 2(a) to 2(d). Accordingly, the back faces of the substrates W are each directed upward.

The substrate transporting robot CR takes the substrate W from the inversion unit RV, and transports the taken substrate W to one of the two inspecting units 20. The substrate W whose back face is directed upward is placed on the stage 121 of the inspecting unit 20 shown in FIG. 6.

### [Step S03] Observing Scratch

The inspecting unit 20 performs inspection to the back face of the substrate W. The inspecting unit 20 detects a scratch, particles, and other projections. In this embodiment, description is particularly made of a case where a scratch formed on the back face of the substrate W is detected.

The lighting portion 125 emits light toward the back face of the substrate W in the inspecting unit 20 shown in FIG. 6. The camera 124 takes a picture of the back face of the substrate W to which light is emitted, thereby capturing an observed image. The camera 124 may take a picture while the XY-direction moving mechanism 122 moves the stage 121 on which the substrate W is placed. Large and small scratches appear in the captured observed image. The inspection controller 130 performs image processing on the observed image, and extracts one or more scratches to be polished where the reflected light is relatively strong, that is, part having luminance higher than a preset threshold. Moreover, the inspection controller 130 may extract a scratch to be polished based on a length of the scratch.

Moreover, the inspecting unit 20 measures a depth of a scratch when the scratch is detected. For example, when a plurality of scratches is detected (extracted), the inspecting unit 20 measures a depth of a representative scratch or depths of the representative scratches. The following describes measurement of the depth of the scratch.

The lifting mechanism 128 (FIG. 6) moves the laser microscope 127 downward to a preset height position. In addition, the XY-direction moving mechanism 122 moves the stage 121 in such a manner that a scratch to be measured is positioned below the objective lens 127A of the laser microscope 127. The stage 121 is moved in accordance with a coordinate of the scratch extracted in the observed image. The laser microscope 127 collects the reflected light through the objective lens 127A while irradiating the scratch (entirely or partially) and its periphery with laser light from the objective lens 127A. As a result, the laser microscope 127 captures a three-dimensional image containing a three-dimensional shape.

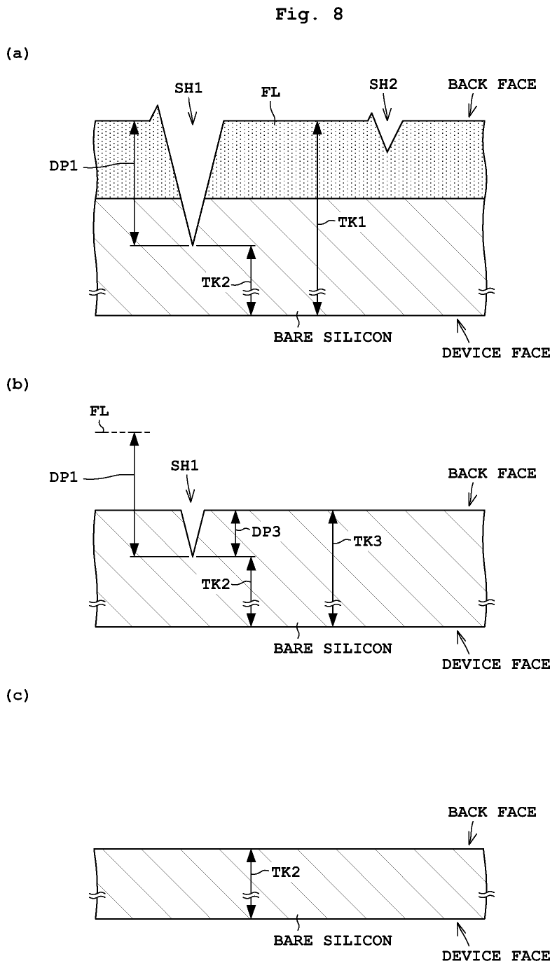

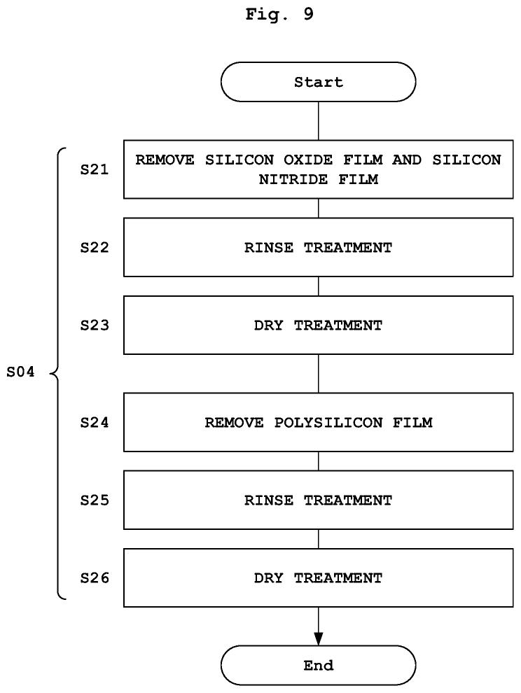

The inspection controller 130 measures a depth of the scratch by performing image processing to the three-dimensional image. FIG. 8(a) is a longitudinal sectional view for explanation of a state of the substrate W prior to an etching step. In FIG. 8(a), it is assumed that a thin film such as a silicon oxide film, a silicon nitride film, and polysilicon is formed on the back face of the substrate W. Moreover, it is assumed that a scratch SH1 on the left side of FIG. 8(a) reaches to bare silicon BSi. In this case, the inspection controller 130 measures a depth of the scratch SH1 (value DP1) from the three-dimensional image obtained by the laser microscope 127.

After the scratch and the like is observed, the substrate transporting robot CR transports the substrate W from the stage 121 of the inspecting unit 20 to any one of six polishing units 22 (U2 to U4). The substrate W whose back face is directed upward is placed on the holding rotator 35 of the polishing unit 22. Then, a magnet not shown causes three holding pins 43A shown in FIG. 4(a) to rotate around the rotary axis AX4. Thereby, the three holding pins 43A hold the substrate W. Here, the substrate W is held while being separated from the spin base 41 and the hot plate 45.

Then, the substrate thickness measuring device 39 measures the thickness of the substrate W prior to a next wet-etching step. A thickness TK1 of the substrate W as shown in FIG. 8(a) is obtained.

### [Step S04] Wet-etching

When the thin film such as a silicon oxide film, a silicon nitride film, and polysilicon film is formed on the back face of the substrate W, the polisher 96 cannot polish the back face of the substrate W suitably. Some of these films are formed unintentionally in the manufacturing step of the device, while others are formed intentionally to suppress warping of the substrate W. Then, the polishing unit 22 removes a film FL formed on the back face of the substrate W by supplying a first chemical liquid (etching solution) to the back face of the substrate W.

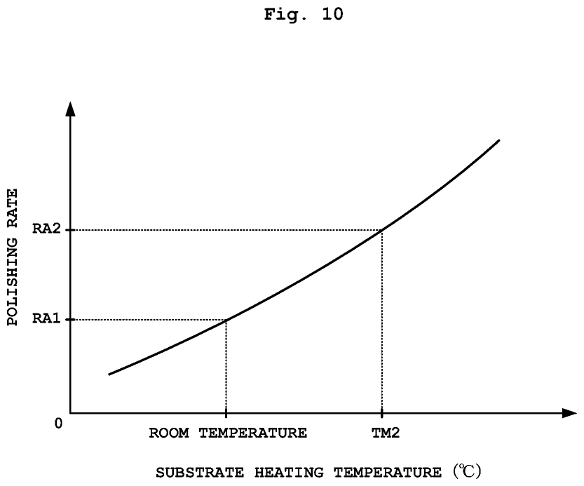

FIG. 9 is a flow chart for explanation of details of the wet-etching step in the step S04. Firstly, a silicon oxide film and a silicon nitride film are removed (step S21).

Here, the gas ejection port 47 provided at a center of the spin base 41 ejects gas. That is, the gas ejection port 47 ejects gas in such a manner that the gas flows in a gap between the substrate W and the spin base 41 from the center of the substrate W toward the outer edge of the substrate W. A device face (front face) of the substrate W faces to the spin base 41. When gas is ejected from the gas ejection port 47, gas jets outward from the gap between an outer edge of the substrate W and the spin base 41. For example, the polishing scraps or a liquid such as the first chemical liquid can be prevented from adhering on the device face of the substrate W. That is, the device face can be protected. Moreover, due to a Bernoulli's effect, a force to absorb the substrate W to the spin base 41 acts.

The nozzle moving mechanism 95 moves the first chemical liquid nozzle 65 from a standby position outside of the substrate W to any treating position above the substrate W. The holding rotator 35 rotates the substrate W while holding the substrate W in a horizontal posture. Then, the first chemical liquid nozzle 65 supplies the first chemical liquid (e.g., hydrofluoric acid) to the back face of the rotating substrate W. Accordingly, the silicon oxide film and the silicon nitride film formed on the back face of the substrate W can be removed.

Here, the first chemical liquid may be supplied while the first chemical liquid nozzle 65 moves horizontally. Moreover, after the first chemical liquid nozzle 65 stops supply of the first chemical liquid, the first chemical liquid nozzle 65 is moved to the standby position outside of the substrate W.

Then, rinse treatment is performed (step S22). That is, the rinse liquid nozzle 73 supplies a rinse liquid (e.g., DIW or carbonated water) to the center of the rotating substrate W. In this way, the first chemical liquid remaining on the back face of the substrate W is washed off toward outside of the substrate. Then, dry treatment is performed (step S23). That is, the rinse liquid nozzle 73 stops supply of the rinse liquid. Then, the holding rotator 35 rotates the substrate W at high speed to dry the substrate W. At this time, the gas nozzle 75 moved above the substrate W may supply gas to the back face of the substrate W. Here, the dry treatment may be performed not by rotating the substrate W at high speed but by supplying gas from the gas nozzle 75.

After the steps S21 to S23, the polysilicon film is removed (step S24). The second chemical liquid nozzle 67 is moved from a standby position outside of the substrate W to any treating position above the substrate W. The holding rotator 35 rotates the substrate W at a preset rotation speed. Then, the second chemical liquid nozzle 67 supplies the second chemical liquid (e.g., a mixed liquid of hydrofluoric acid (HF) and nitric acid (HNO₃)) to the back face of the rotating substrate W. Accordingly, the polysilicon film formed on the back face of the substrate W can be removed.

The second chemical liquid may be supplied while the second chemical liquid nozzle 67 moves horizontally. Moreover, after the second chemical liquid nozzle 67 stops supply of the second chemical liquid, the second chemical liquid nozzle 67 is moved to the standby position outside of the substrate W.

Then, substantially similar to the case of the first chemical liquid (steps S22 and S23), rinse treatment (step S25) is performed and thereafter dry treatment (step S26) is performed. The holding rotator 35 stops rotation of the substrate W.

### [Step S05] Back Polishing of Substrate W

After the wet-etching step, the polishing unit 22 polishes the back face of the substrate W. Such polishing is performed especially when the inspecting unit 20 detects a scratch on the back face of the substrate W. Detailed description is as under.

The holding rotator 35 rotates the substrate W while holding the substrate W in a horizontal posture. The arm rotating mechanism 117 of the polishing mechanism 37 (FIG. 5) rotates the polisher 96 and the arm 101 around the vertical axis AX6. Accordingly, the polisher 96 is moved from the standby position outside of the substrate W to a preset position above the substrate W. Moreover, the electric motor 104 of the polishing mechanism 37 rotates the polisher 96 around the vertical axis AX5 (shaft 100).

Moreover, the hot plate 45 heats the substrate W with heat generated by passing current. The temperature sensor 46 of a non-contact type monitors a temperature of the substrate W. The main controller 134 adjusts heat from the hot plate 45 in accordance with the temperature of the substrate W detected by the temperature sensor 46. A heating temperature of the substrate W is adjusted to a temperature higher than room temperature (e.g., 25° C.) for obtaining a high polishing rate. Note that it is preferred to adjust the heating temperature 100° C. or lower for avoiding thermal degradation of the polisher 96.

Then, the electropneumatic regulator 115 supplies gas, having pressure in accordance with the electrical signal, to the air cylinder 113. Accordingly, the air cylinder 113 moves the polisher 96 and the arm 101 downward to contact the polisher 96 against the back face of the substrate W. The polisher 96 is pressed against the back face of the substrate W at preset contact pressure. This achieves polishing. When the polishing is performed, the arm rotating mechanism 117 of the polishing mechanism 37 (FIG. 5) swings the polisher 96 and the arm 101 around the vertical axis AX6. That is, the polisher 96 reciprocates repeatedly between a position adjacent to the center of the back face and a position adjacent to the outer edge of the substrate W, for example.

Now, regarding an amount of polishing in the thickness direction (Z-direction) of the substrate W, it is considered unnecessary to perform polishing as long as the substrate W satisfies a preset flatness even if a scratch exists. However, an edge of the scratch may create a new damage on the stage of an exposing machine, for example. Accordingly, polishing is performed until a scratch having a preset size is eliminated.

As shown in FIG. 8(a), the depth of the scratch SH1 (value DP1) is obtained by the laser microscope 127. Accordingly, the polishing unit 22 polishes the back face of the substrate W until a thickness corresponding to the depth of the scratch SH1 (value DP1) determined by the laser microscope 127, is scraped off. The thickness corresponding to the depth of the scratch SH1 is the value DP1. Polishing is performed until the thickness of the substrate W is brought into a value TK2 (=TK1-DP1). The thickness of the substrate W is periodically measured by the substrate thickness measuring device 39. When comparison is made between a measured value and a target value (e.g., value TK2) of the substrate thickness and then if the measured value does not reach the target value, the main controller 134 controls to perform polishing continuously.

Now, FIG. 8(b) is a view illustrating a state after the etching step (step S04). When the film FL is removed by the etching step, the depth of the scratch SH1 is decreased. Accordingly, an amount of polishing is made small in the up-down direction, whereas polishing is performed continuously until the thickness of the substrate W is brought into the value TK2. FIG. 8(c) is a view illustrating a state after the polishing step (step S05). Now, a scratch SH2 shown in FIG. 8(a) does not reach to bare silicon. Such a scratch is removed together when the film FL such as silicon oxide film is removed.

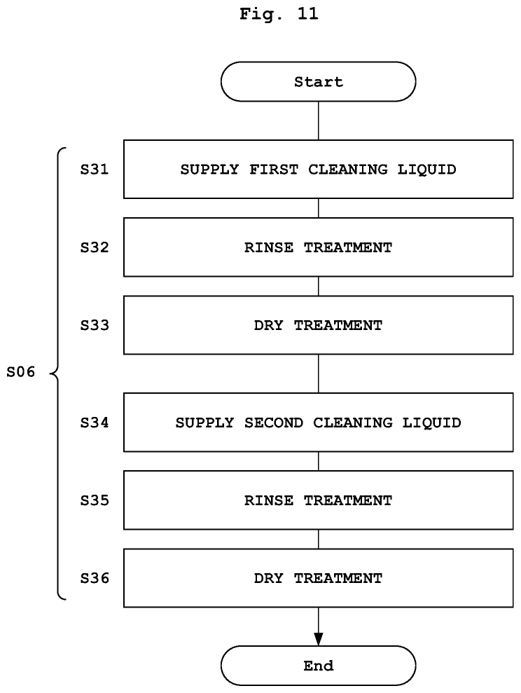

The substrate W is heated by the hot plate 45. FIG. 10 illustrates a relationship between the heating temperature and the polishing rate of the substrate W. The contact pressure of the polisher 96, the rotation speed of the substrate W and the like are constant. Here, polishing rate increases when a temperature TM2 of the substrate W becomes high relative to a case where the temperature of the substrate W is room temperature (e.g., 25° C.), for example. Accordingly, heating the substrate W by hot plate 45 can increase the polishing rate. This can shorten time for polishing treatment.

When polishing is performed, the polishing unit 22 may adjust the polishing rate by controlling the heating temperature of the substrate W by the hot plate 45. Raising and lowering the heating temperature of the substrate W allows increase and decrease of the polishing rate. The polishing rate may be adjusted prior to or during the polishing. For example, the polishing rate can be made different between the part adjacent to the center of the substrate W and the part adjacent to the outer edge of the substrate W by changing the temperature of the substrate W between the part adjacent to the center of the substrate W and the part adjacent to the outer edge of the substrate W. Now, the polisher 96 is moved to the standby position of the substrate W.

### [Step S06] Cleaning Substrate W

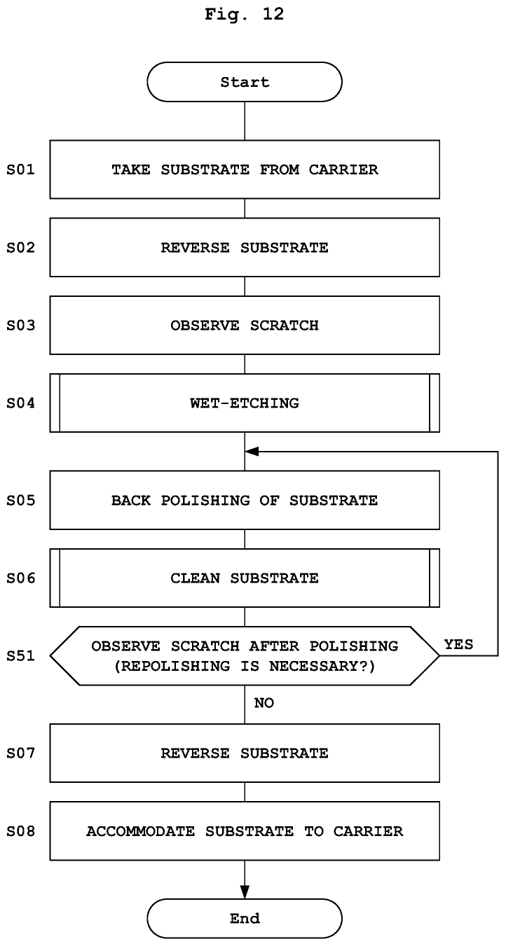

After the back face of the substrate W is polished, the back face of the substrate W is cleaned. Accordingly, polishing scraps remaining on the back face of the substrate W are removed, and metal, organic matters and particles are removed. FIG. 11 is a flow chart showing procedures of a cleaning step in the step S06.

Firstly, a first cleaning liquid is supplied to the back face of the substrate W (step S31). Detailed description is as under. The holding rotator 35 keeps holding of the substrate W. Moreover, the holding rotator 35 keeps protecting the device face of the substrate W by ejecting gas from the gas ejection port 47. The first cleaning liquid nozzle 69 is moved from a standby position outside of the substrate W to any treating position above the substrate W. The holding rotator 35 rotates the substrate W. Then, the first cleaning liquid nozzle 69 supplies a first cleaning liquid (e.g., SC2 or SPM) to the back face of the rotating substrate W. The first cleaning liquid may be supplied while the first cleaning liquid nozzle 69 moves horizontally.

After the first cleaning liquid is supplied to perform the cleaning treatment, rinse treatment is performed (step S32). That is, the rinse liquid nozzle 73 supplies a rinse liquid (DIW or carbonated water) to the center of the rotating substrate W. In this way, the first cleaning liquid remaining on the back face of the substrate W is washed off. Then, dry treatment is performed (step S33). That is, the rinse liquid nozzle 73 stops supply of the rinse liquid. Then, the holding rotator 35 rotates the substrate W at high speed to dry the substrate W. At this time, the gas nozzle 75 moved above the substrate W may supply gas to the back face of the substrate W. Here, the dry treatment may be performed not by rotating the substrate at high speed but by supplying gas from the gas nozzle 73.

After the steps S31 to S33, a second cleaning liquid is supplied (step S34). That is, the second cleaning liquid nozzle 71 is moved from a standby position outside of the substrate W to any treating position above the substrate W. The holding rotator 35 rotates the substrate W at a preset rotation speed. Then, the second cleaning liquid nozzle 71 supplies the second cleaning liquid (e.g., SC1) to the back face of the rotating substrate W.

The second cleaning liquid may be supplied while the second cleaning liquid nozzle 71 moves horizontally. After the second cleaning liquid nozzle 71 stops supply of the second cleaning liquid, the second cleaning liquid nozzle 71 is moved to the standby position outside of the substrate W.

Then, substantially similar to the case of the first cleaning liquid (steps S32 and S33), rinse treatment (step S35) is performed and thereafter dry treatment (step S36) is performed. The holding rotator 35 stops rotation of the substrate W. Since the polishing unit 22 in this embodiment has a cleaning function, the substrate W from which polishing scraps are cleaned off can be unloaded from the polishing unit 22.

### [Step S07] Reversing Substrate W

The substrate transporting robot CR takes the substrate W from the polishing unit 22, and transports the taken substrate W to the inversion unit RV. At this time, the back face of the substrate W is directed upward while the device face of the substrate W is directed downward. When one substrate W or two substrates W are placed on the mount members 28A, 28B by the substrate transporting robot CR, the inversion unit RV reverses the two substrates W as shown in FIGS. 2(a) to 2(d). Accordingly, the back faces of the substrates W are each directed downward.

### [Step S08] Accommodation of Substrate W to Carrier C

The indexer robot 9 takes the substrate W from the inversion unit RV, and returns the substrate W to the carrier C.

According to this embodiment, the polishing unit 22 includes the holding rotator 35, the hot plate 45 (heating member), and the polisher 96. The polisher 96 polishes the back face of the substrate W in the chemo-mechanical grinding (CMG) manner by contacting against the back face of the rotating substrate W. When such polishing is performed, the substrate W is heated by the hot plate 45. When the substrate W is heated, the polishing rate can increase (see FIG. 10). This can shorten time for polishing treatment.

Moreover, the inspecting unit 20 for inspecting the substrate W detects a scratch formed on the back face of the substrate W before the back face of the substrate W is polished. Moreover, the inspecting unit 20 polishes the back face of the substrate W when a scratch is detected. This can scrape the detected scratch, i.e., a selected scratch.

Moreover, the inspecting unit 20 measures a depth of a scratch when the scratch is detected. The polishing unit 22 polishes the back face of the substrate W until a thickness corresponding to the depth of the scratch measured by the inspecting unit 20 is scraped off. Accordingly, the depth of the scratch is recognized, achieving a suitable amount of polishing in a thickness direction of the substrate W.

With the substrate treating apparatus 1, the polisher 96 polishes the back face of the substrate W in the chemo-mechanical grinding (CMG) manner by contacting against the back face of the rotating substrate W. Here, it is found that, when a film FL is formed on the back face of the substrate W, the polishing cannot be performed suitably due to the film FL. Then, the film FL formed on the back face of the substrate W is removed by etching treatment prior to polishing treatment. This can perform the polishing treatment suitably.

### SECOND EMBODIMENT

The following describes a second embodiment of the present invention with reference to the drawings. Here, the description common to that of the first embodiment is to be omitted. FIG. 12 is a flow chart illustrating operation of a substrate treating apparatus according to the second embodiment.

In the first embodiment, scratch observation is not performed after a back face of a substrate W is polished (step S05). In this regard, scratch observation is performed after a back face of a substrate W is polished (step S51 in FIG. 12) in the second embodiment.

Here, operation substantially same as that in the steps S01 to S08 shown in FIG. 7 is performed in the steps S01 to S08 shown in FIG. 12, respectively. After the cleaning step of the substrate W (step S06), the substrate transporting robot CR takes the substrate W from the polishing unit 22, and transports the substrate W to a stage 121 of one of the two inspecting units 20.

[Step S51] Observing Scratch after Polishing

The inspecting unit 20 especially detects the scratch formed on the back face of the substrate W again. That is, similar to the operation of step S03, the inspecting unit 20 acquires an observed image by the camera 124 and the lighting portion 125. The inspection controller 130 extracts a scratch to be polished by performing image processing to the acquired observed image. When a scratch to be polished is not extracted, the main controller 134 determines that repolishing is unnecessary, and the procedure proceeds to the step S07.

In contrast to this, when a scratch to be polished is extracted, the main controller 134 determines that repolishing is necessary. Then, the inspecting unit 20 measures a depth of the scratch to be polished. That is, the laser microscope 127 captures a three-dimensional image containing the scratch to be polished. The inspection controller 130 measures a depth of the scratch to be polished (value DP3 in FIG. 8(b)) by performing image processing to the obtained three-dimensional image.

Thereafter, the substrate transporting robot CR transports the substrate W from the stage 121 of the inspecting unit 20 to the holding rotator 35 of the polishing unit 22. After the transportation, the substrate W is held by the holding rotator 35, and gas is ejected from the gas ejection port 47. Then, the substrate thickness measuring device 39 is moved above the substrate W, and measures a thickness of the substrate W (value TK3 in FIG. 8(b)). The procedure returns to the step S05.

In the step S05, the polishing unit 22 again polishes the back face of the substrate W when the inspecting unit 20 extracts the scratch to be polished. The polishing is performed until the thickness (value DP3) corresponding to the depth of the scratch is scraped off. In other words, polishing is performed until the thickness of the substrate W is brought into a value TK2 (=TK3−DP3) shown in FIG. 8(b).

According to this embodiment, since polishing is performed until the scratch to be polished that needs polishing is eliminated, a new damage on the stage of the exposing machine, for example, caused by the edge of the scratch may be prevented.

Moreover, when a scratch to be polished is present in this embodiment, the wet-etching step (step S04) is not performed. In this regard, the wet-etching may be performed as necessary.

### THIRD EMBODIMENT

The following describes a third embodiment of the present invention with reference to the drawings. Here, the description common to that of the first and second embodiments is to be omitted.

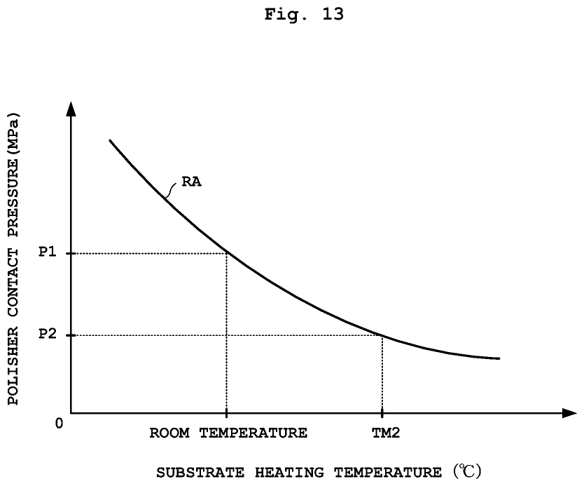

FIG. 13 illustrates a relationship between a heating temperature of a substrate W and a contact pressure (press) of a polisher 96. FIG. 13 is a view where the polishing rate is made constant. In FIG. 13, it is assumed that a given polishing rate RA is obtained when the substrate W has the temperature of room temperature (e.g., 25° C.) and given contact pressure P1. When the substrate W is heated, the polishing rate increases. Accordingly, a contact pressure P2 lower than the contact pressure P1 is obtainable when the temperature is made higher than room temperature (e.g., temperature TM2) while the polishing rate RA is maintained. That is, if the polishing rate RA is constant, the contact pressure can be lowered by raising the temperature of the substrate W.

With this embodiment, the polishing unit 22 can adjust the polishing rate by controlling the contact pressure of the polisher 96 against the substrate W in addition to the heating temperature of the substrate W. For example, raising the heating temperature of the substrate W while keeping the polishing rate allows decreased contact pressure of the polisher 96 against the substrate W. This can suppress load of the substrate W caused by the contact pressure. That is, excess pushing against the substrate W can be prevented.

Here, adjustment of the polishing rate is not limitedly performed from a relationship between the heating temperature of the substrate W and the contact pressure of the polisher 96. That is, adjustment of the polishing rate may be performed with use of a relationship between the heating temperature of the substrate W and a moving speed of the polisher 96. Moreover, adjustment of the polishing rate may be performed with use of a relationship between the heating temperature of the substrate W and a moving speed of the polisher 96 around the vertical axis AX6 (swinging speed). Adjustment of the polishing rate may be performed with use of a relationship between the heating temperature of the substrate W and a rotation speed of the polisher 96 around the vertical axis AX5. Adjustment of the polishing rate may be performed with use of a relationship between the heating temperature of the substrate W and a rotation speed of the substrate W.

That is, the polishing unit 22 may adjust the polishing rate by controlling at least one selected from the contact pressure of the polisher 96 against the substrate W, the moving speed of the polisher 96, the rotation speed of the polisher 96, and the rotation speed of the substrate W in addition to the heating temperature of the substrate W.

### FOURTH EMBODIMENT

A fourth embodiment of the present invention will now be described with reference to the drawings. Here, the description common to that of the first to third embodiments is to be omitted.

In FIG. 1, the treating unit U1 corresponds to the inspecting unit 20 and each of the treating units U2 to U4 corresponds to the polishing unit 22 in the first embodiment. In the fourth embodiment, each of the treating units U2 and U3 may correspond to a polishing unit 141, and the treating unit U4 may correspond to a liquid treating unit 143. Here, the treating unit U1 corresponds to the inspecting unit 20.

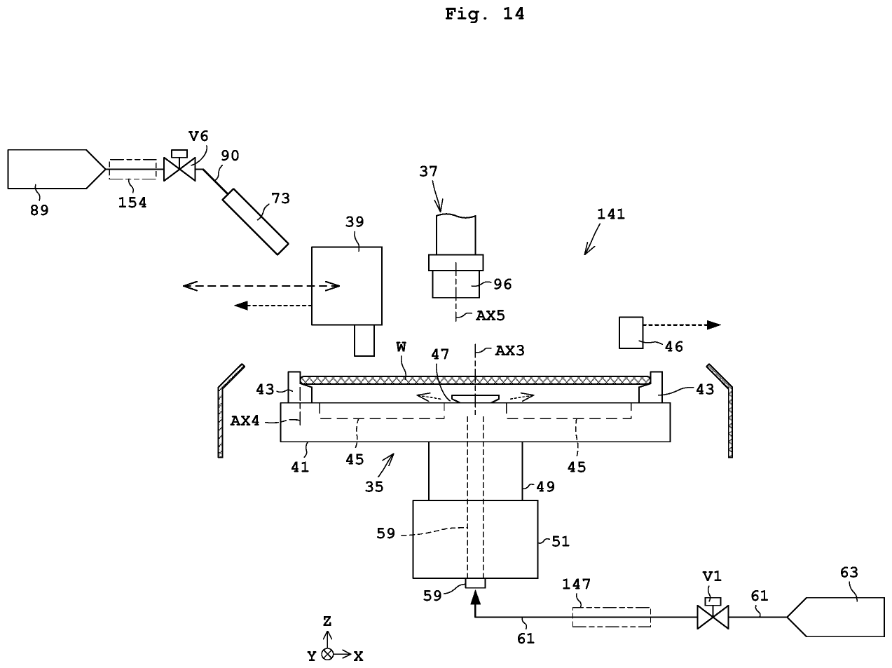

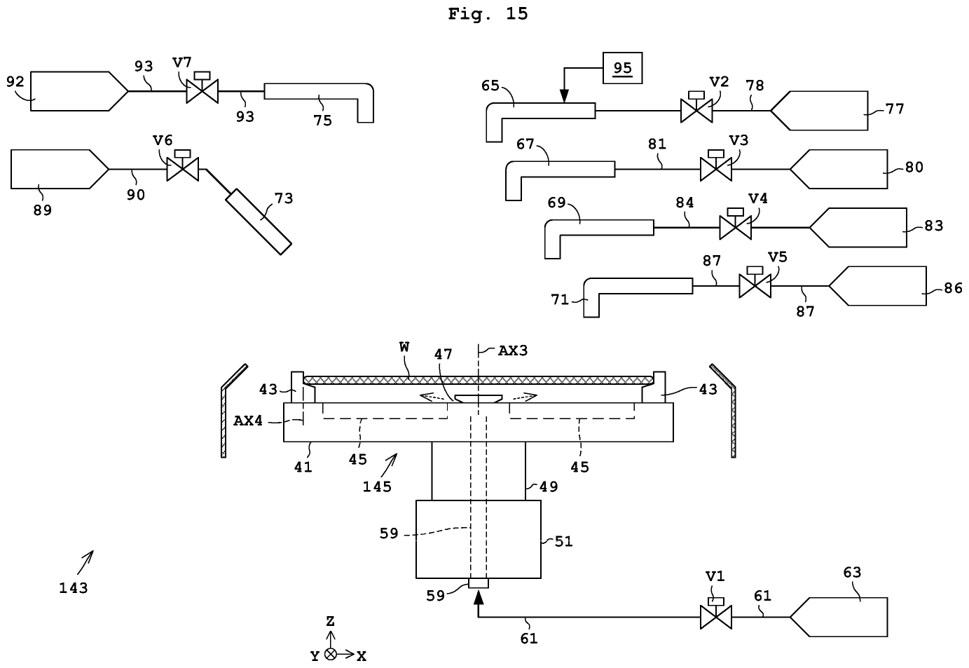

That is, the substrate treating apparatus 1 in the fourth embodiment includes a two-layered inspecting unit 20, two-layered two polishing units 141, and a two-layered liquid treating unit 143. In other words, the substrate treating apparatus 1 includes eight treating units U1 to U4. FIG. 14 illustrates the polishing unit 141 according to the fourth embodiment. FIG. 15 illustrates the liquid treating unit 143 according to the fourth embodiment.

The polishing unit 141 and the liquid treating unit 143 are formed by dividing the polishing unit 22 in FIG. 3 into two, for example. Here, the liquid treating unit 143 includes a second holding rotator 145 that is configured in the same manner as the holding rotator 35. Moreover, the polishing unit 141 may include a rinse liquid nozzle 73, a rinse liquid supplying source 89, and a rinse liquid pipe 90. Here, the polishing units 22 and 141 correspond to the polishing unit in the present invention.

The substrate treating apparatus 1 operates in accordance with the flow chart shown in FIG. 7 or FIG. 12. However, the substrate W is transported between the polishing unit 141 and the liquid treating unit 143, for example. In the steps S03 to S06 in FIG. 7, for example, the substrate W is transported by the substrate transporting robot CR to the inspecting unit 20, the liquid treating unit 143 (wet-etching step), the polishing unit 141, and the liquid treating unit 143 (cleaning step of the substrate W) in this order.

This embodiment produces the same effect as that of the first embodiment. Moreover, the polishing unit 141 and the liquid treating unit 143 can each be made compact since they are formed by dividing the polishing unit 22 in FIG. 2 into two, for example.

Here, the polishing unit 141 may be provided with a construction concerning the wet-etching step (step S04) in the liquid treating unit 143. Moreover, the polishing unit 141 may be provided with a construction concerning the cleaning step (step S06) of the substrate W in the liquid treating unit 143. Moreover, in the fourth embodiment, the polishing unit 141 does not include heaters 147, 154 (see FIG. 14) mentioned later.

The present invention is not limited to the foregoing examples, but may be modified as follows.

(1) In the embodiments described above, the polishing unit 22 includes the hot plate 45 as the heating member. Instead of the hot plate 45, the polishing unit 22 may be configured such that the gas ejection port 47 ejects heated gas. Heated gas from the gas ejection port 47 can heat the substrate. In this case, the polishing unit 22 may include a heater 147 (see FIGS. 3 and 14) for heating gas, passing through the gas pipe 61, from outside of the gas pipe 61, for example. Here, the polishing unit 22 does not necessarily include the hot plate 45. Moreover, the substrate W may be heated by both the hot plate 45 and the heated gas ejected from the gas ejection port 47. The gas ejection port 47 corresponds to the heating member in the present invention.

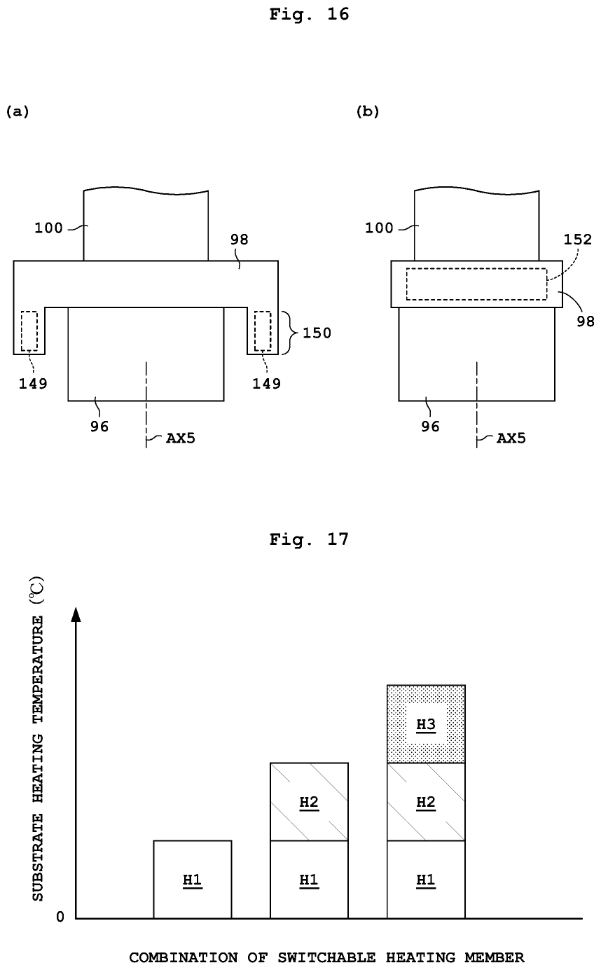

(2) In the embodiments and the modification (1) described above, the polishing unit 22 includes the hot plate 45 as the heating member. In this regard, as shown in FIGS. 16(a) and 16(b), the polishing unit 22 may include a heater 149 (152), instead of the hot plate 45, for heating the polisher 96. Alternatively, the polishing unit 22 may include the hot plate 45 and the heater 149 (152). In FIG. 16(a), an attachment member 98 is configured like a vessel whose lower face is recessed. The heater 149 in a ring shape is provided on a hollow tubular portion 150 of the attachment member 98 surrounding the polisher 96 (vertical axis AX5). The heater 149 heats the polisher 96. When the polisher 96 is heated, the substrate W can be heated via the polisher 96. Moreover, an interface between the polisher 96 and the back face of the substrate W can be heated effectively.

Moreover, as shown in FIG. 16(b), the heater 152 may be embedded in the attachment member 98 and arranged between the shaft 100 and the polisher 96. Here, the heaters 149 and 152 may each perform heating with an electric heater such as a nichrome wire, for example. Moreover, the heaters 149 and 152 may each include a pipe and perform heating by supplying heated gas or a heated liquid through the pipe. The heaters 149 and 152 each correspond to the heating member in the present invention.

(3) In the embodiments and the modifications described above, the back face of the substrate W is polished with the polisher 96 in the dry chemo-mechanical grinding manner. In this regard, the polisher 96 may polish the back face of the substrate W in the chemo-mechanical grinding manner by supplying a liquid over the back face of the substrate W. For example, the rinse liquid nozzle 73 (FIGS. 3 and 14) may supply heated pure water (e.g., DIW) over the back face of the substrate W and in the vicinity of the polisher 96. Heated pure water can heat the substrate W. Moreover, heated pure water can clean off the polishing scraps from the back face of the substrate W. For example, the polishing unit 22 (141) may include a heater 154 for heating pure water, passing through the rinse liquid pipe 90, from outside of the rinse liquid pipe 90. Moreover, the substrate W may be heated by the heated pure water from the rinse liquid nozzle 73 without being heated by the hot plate 45. In this case, the polishing unit 22 does not necessarily include the hot plate 45. Here, the rinse liquid nozzle 73 corresponds to the heating member in the present invention.

Moreover, the substrate W may be heated by at least one selected from the hot plate 45, the gas ejection port 47 that ejects heated gas, the heater 149 (or heater 152) for heating the polisher 96, and the rinse liquid nozzle 73 for supplying the heated pure water to the back face of the substrate W.

Moreover, the polishing unit 22 may include these heating members, and may combine the heating members for controlling the heating temperature of the substrate W. For example, it is assumed that heating is performed only by the hot plate 45 (numeral H1 in FIG. 17). When more heating is required, the substrate W may be heated by the gas ejection port 47, in addition to the hot plate 45, that ejects heated gas (numeral H1 and numeral H2 in FIG. 17). Moreover, when further heating is required, the substrate W may be heated by the heater 149 (or heater 152), in addition to the hot plate 45 and the gas ejection port 47, that heats the polisher 96 (numeral H1, numeral H2, and numeral H3 in FIG. 17). When heating needs to be suppressed from this state, the substrate W may be heated only by the hot plate 45 (numeral H1).

(4) In the embodiments and the modifications described above, the substrate thickness measuring device 39 measures the thickness of the substrate W prior to the wet-etching step (step S04). In this regard, the substrate thickness measuring device 39 may measure the thickness of the substrate W between the step S04 and the back polishing step (step S05) of the substrate W. In this case, the scratch observing step (step S03) may be shifted between the steps S04 and S05.

(5) In the embodiments and modifications described above, the polishing unit 22 and the main controller 134 are provided in the substrate treating apparatus 1 together with the indexer block 3 and the like. In this regard, the polishing unit 22 and the main controller 134 may be provided in the polishing device.

(6) In the embodiments and modifications described above, the contact pressure of the polisher 96 against the substrate W may be detected by a load cell, for example. Moreover, the moving speed of the polisher 96 may be detected by a rotary encoder that detects an angle of the polisher 96 around the vertical axis AX6. Moreover, the rotation speed of the polisher 96 may be detected by a rotary encoder that detects an angle of the polisher 96 around the vertical axis AX5. Moreover, the rotation speed of the substrate W may be detected by a rotary encoder that detects an angle of the substrate W around the rotary axis AX3. The main controller 134 may control each component based on these detected results.

(7) In the embodiments and the modifications mentioned above, the holding rotator 35 holds the substrate W, whose back face is directed upward, in a horizontal posture. Moreover, the spin base 41 of the holding rotator 35 is arranged below the substrate W. In this regard, the holding rotator 35 may be arranged upside down. That is, the spin base 41 of the holding rotator 35 is arranged above the substrate W. Moreover, the holding rotator 35 holds the substrate W, whose back face is directed downward, in a horizontal posture. In this case, the polisher 96 is brought into contact against the substrate W whose back face is directed downward from a side below the substrate W.

(8) In the embodiments and the modifications described above, the steps S21 to S26 are performed as the wet-etching step (FIG. 9). Among the six steps S21 to S26, only the steps S21 to S23 may be performed. Moreover, among the six steps S21 to S26, only the steps S24 to S26 may be performed.

(9) In the embodiments and the modifications described above, the steps S31 to S36 are performed as the cleaning step of the substrate W (FIG. 11). Among the six steps S31 to S36, only the steps S31 to S33 may be performed. Moreover, among the six steps S31 to S36, only the steps S34 to S36 may be performed.

### REFERENCE SIGNS LIST

1 . . . substrate treating apparatus
20 . . . inspecting unit
22, 141 . . . polishing unit
35 . . . holding rotator
37 . . . polishing mechanism
41 . . . spin base
43 . . . holding pin
45 . . . hot plate
47 . . . gas ejection port
65 . . . first chemical liquid nozzle
67 . . . second chemical liquid nozzle
73 . . . rinse liquid nozzle
96 . . . polisher
117 . . . arm rotating mechanism
127 . . . laser scanning confocal microscope
130 . . . inspection controller
134 . . . main controller
145 . . . second holding rotator
147, 149, 152, 154 . . . heater

1. A polishing method, comprising:
a rotating step of rotating a substrate in a horizontal posture:
an etching step of supplying an etching solution to a back face of the substrate to remove a film formed on the back face of the substrate; and
a polishing step of polishing the back face of the substrate in a chemo-mechanical grinding manner by contacting a polisher against the back face of the substrate after the film on the back face of the substrate is removed, the polisher having a resin body where abrasive grains are distributed.

2. The polishing method according to claim 1, further comprising:
a heating step of heating the substrate during polishing.

3. The polishing method according to claim 2, further comprising:
a controlling step of adjusting a polishing rate by controlling a heating temperature of the substrate in the heating step.

4. The polishing method according to claim 3, wherein
in the controlling step, the polishing rate is adjusted by controlling at least one selected from a contact pressure of the polisher against the substrate, a moving speed of the polisher, a rotation speed of the polisher, and a rotation speed of the substrate.

5. The polishing method according to any of claims 1 to 4, wherein the etching step includes removal of a silicon oxide film.

6. The polishing method according to any of claims 1 to 4, wherein the etching step includes removal of a silicon nitride film.

7. The polishing method according to any of claims 1 to 4, wherein the etching step includes removal of a polysilicon film.

8. The polishing method according to any of claims 1 to 4, further comprising:
an inspecting step of detecting a scratch formed on the back face of the substrate prior to the etching step by an inspecting unit, wherein
the etching step is performed when the inspecting unit detects the scratch.

9. The polishing method according to claim 8, wherein
in the inspecting step, the inspecting unit detects the scratch formed on the back face of the substrate and determines a depth of the scratch when the scratch is detected,
the etching step is performed when the inspecting unit detects the scratch, and
in the polishing step, the back face of the substrate is polished until a thickness corresponding to the depth of the scratch determined by the inspecting unit is scraped off.

10. The polishing method according to any of claims 1 to 4, further comprising:
a detecting step of detecting a scratch formed on the back face of the substrate between the etching step and the polishing step by an inspecting unit, wherein
the polishing step is performed when the inspecting unit detects the scratch.

11. A substrate treating apparatus, comprising:
a holding rotator configured to rotate a substrate while holding the substrate in a horizontal posture:
a polisher having a resin body where abrasive grains are distributed,
an etching solution supply nozzle configured to supply an etching solution to a back face of the substrate held by the holding rotator; and
a controller, wherein
the controller causes the etching solution supply nozzle to supply the etching solution to the back face of the substrate to remove a film formed on the back face of the substrate, and
the controller causes the polisher to contact against the back face of the rotating substrate after the film on the back face of the substrate is removed to polish the back face of the substrate in a chemo-mechanical grinding manner.

12. The substrate treating apparatus according to claim 11, further comprising:
a heating member configured to heat the substrate, wherein
after the film on the back face of the substrate is removed, the controller causes the polisher to contact against the back face of the substrate heated while being rotated to polish the back face of the substrate in the chemo-mechanical grinding manner.
